(19) United States
(12) Patent Application Publication
(10) Pub. No.: US 2022/0138365 A1
(43) Pub. Date: May 5, 2022

(54) SYSTEMS AND METHODS FOR POINT CLOUD SITE COMMISSIONING

(71) Applicant: Crown Equipment Corporation, New Bremen, OH (US)

(72) Inventors: Timothy Fuchs, Auckland (NZ); Christopher Leigh Beaumont, Auckland (NZ)

(73) Assignee: Crown Equipment Corporation, New Bremen, OH (US)

(21) Appl. No.: 17/513,104

(22) Filed: Oct. 28, 2021

Related U.S. Application Data
(60) Provisional application No. 63/107,693, filed on Oct. 30, 2020.

(51) Int. Cl. G06F 30/13; G06F 30/12; G06T 17/00

(52) U.S. Cl. CPC G06F 30/13; G06T 2200/04; G06T 17/00; G06F 30/12

(57) ABSTRACT

Systems and methods for site commissioning to generate accurate representations and models of warehouse infrastructure. In one embodiment, a method of site commissioning includes receiving point cloud data for warehouse infrastructure and using point cloud data by a site commissioning tool to overlay infrastructure models, and generate an infrastructure model. The site commissioning tool may combine bay models with three-dimensional location information of the point cloud data to generate accurate representations of the warehouse infrastructure including the location of infrastructure elements and characteristics of the warehouse infrastructure, such as bay opening dimensions. Generating an accurate representation of bay models provides a parametric definition of as-built infrastructure. A method is also provided for condition point cloud data for use in a site commissioning tool. Some embodiments are directed to a site commissioning user interface for a site commissioning tool.

### CROSS-REFERENCE TO RELATED APPLICATIONS

This application claims the benefit of U.S. Provisional Application Ser. No. 63/107,693 entitled SYSTEMS AND METHODS FOR POINT CLOUD SITE COMMISSIONING filed Oct. 30, 2020.

### BACKGROUND

For a variety of reasons, the locations and dimensions of warehouse storage infrastructure frequently deviate from design plans and electronic records for a warehouse. Discrepancies between infrastructure records and actual locations and dimensions are often significant enough to negatively affect machine operation in a warehouse. Conventional systems and records for warehouses and warehouse storage locations typically do not provide spatial data, such as coordinates and dimensions, for storage areas. Moreover, warehouse features may require infrastructure to deviate from planned storage locations. Similarly, installations of warehouse infrastructure that deviate from planned locations can result in discrepancies between actual warehouse infrastructure locations or dimensions and design plans.

Existing commissioning processes only allow for detection of commissioning errors, either due to discrepancies between the as-designed and as-built layout of the warehouse, or due to human error, after the system has been deployed. As such, a significant time gap can arise between initial engagement and operation of a site. In addition, deviations from a planned site may not be detected until the site is in use. Correction of a commissioning errors can require significant time, require deployment of resources, and require personnel to identify and correct.

### SUMMARY

Embodiments of the present disclosure are directed to systems and methods for site commissioning. A system for site commissioning includes at least one receiver configured to receive point cloud data for infrastructure of a site and at least one site commissioning processor. The at least one site commissioning processor configured to perform a plurality of functional operations using the point cloud data and at least one model, the plurality of functional operations including receiving at least one model for at least a portion of the point cloud data, and generating an infrastructure model for the infrastructure of the site, wherein coordinates of the point cloud data are incorporated with the at least one model.

In one embodiment, point cloud data includes a plurality of points and includes location coordinates for each point in a coordinate system, and wherein the coordinate system is one of a two-dimensional and three-dimensional coordinate system.

In one embodiment, the at least one model is a bay model type selected for the portion of the point cloud data, and wherein the site commission tool is configured to operate with a plurality of bay model types.

In one embodiment, the at least one model is at least one of an obstacle model, aisle rack model, bay opening model, automation interaction point model point of egress model and hazard model.

In one embodiment, receiving the at least model includes detecting overlay, by the site commissioning tool, of the at least one model to a display of the point cloud.

In one embodiment, the infrastructure for the site includes warehouse infrastructure, and the infrastructure model includes a model for at least one warehouse rack including a plurality of bays.

In one embodiment, generating the infrastructure model includes receiving a plurality of models for the point cloud data and combining model selections.

In one embodiment, the point cloud data provides location coordinates for infrastructure elements of the site, and wherein generating the infrastructure model includes matching locations of the infrastructure model with location of infrastructure elements.

In one embodiment, the at least one site commissioning processor slices the point cloud data to generate point cloud data relevant to a portion of a site.

In one embodiment, the at least one site commissioning processor outputs the infrastructure model at least one of a display and a storage device.

According to another embodiment, a method is provided for site commissioning with point cloud data. The method includes receiving, by a site commissioning tool, point cloud data for infrastructure of a site. The method also includes performing, by the site commissioning tool, a plurality of functional operations using the point cloud data and at least one model. The plurality of functional operations include receiving at least one model for at least a portion of the point cloud data and generating an infrastructure model for the infrastructure of the site, wherein coordinates of the point cloud data are incorporated with the at least one model.

According to embodiments, a method is provided to receive point cloud data for warehouse infrastructure and determine at least one warehouse infrastructure model for the point cloud data. The method can include combining bay models with three-dimensional location data of the point cloud data to generate accurate representations of the warehouse infrastructure, such as an infrastructure model, including the location of infrastructure elements and characteristics of the warehouse infrastructure.

Another embodiment is directed to conditioning point cloud data for use in a site commissioning tool. A method is provided to slice and/or process point cloud data to generate data relevant to a site commissioning tool for commissioning warehouse infrastructure. Point cloud data may be processed to generate a presentation of a portion of warehouse, such an aisle rack face. Conditioning point cloud data can include down sampling and/or other processing for at least one of optimizing visual utility, reducing data load, and removal of non-warehouse infrastructure.

Another embodiment is directed to a site commissioning user interface. A site commissioning tool can present a user interface providing graphical display elements to generate accurate representations of warehouse infrastructure. The graphical user interface can display point cloud data for at least a portion of a warehouse, such as an aisle rack face, and provide at least one graphical element for assigning warehouse infrastructure models, such as bay models, to the point cloud data.

It is to be understood that both the foregoing general description and the following detailed description present embodiments that are intended to provide an overview or framework for understanding the nature and character of the claims. The accompanying drawings are included to provide a further understanding of the disclosure, and are incorporated into and constitute a part of this specification. The drawings illustrate various embodiments and together with the description serve to explain the principles and operation.

### BRIEF DESCRIPTION OF THE DRAWINGS

FIG. 1 illustrates an example method of site commissioning;

FIG. 2 illustrates an example of warehouse infrastructure;

FIG. 3 illustrates an example representation of point cloud data for warehouse infrastructure;

FIGS. 4A, 4B, 4C, and 4D graphically illustrate a process for site commissioning of warehouse infrastructure;

FIG. 5 graphically illustrates examples of bay models;

FIG. 6 illustrates a process for conditioning point cloud data for a site commissioning tool;

FIGS. 7A and 7B graphically illustrate a site commissioning user interface; and

FIG. 8 illustrates a site commissioning tool configuration.

### DETAILED DESCRIPTION OF THE DISCLOSURE

Embodiments of the present disclosure are directed to systems and methods for site commissioning to generate accurate representations and models of site infrastructure, such as warehouse infrastructure and infrastructure in general. Particularly, the methods and systems described herein take as input point cloud data for site infrastructure. As used herein, point cloud data can include a plurality of points, with each point having a location, such as coordinates) assigned to itself. Point cloud data as used by embodiments can be based on one or more coordinate systems and apply to two-dimensional coordinates and/or three-dimensional coordinate systems. According to embodiments, the point cloud data is utilized by a site commissioning tool to overlay infrastructure models and generate an infrastructure model. By way of example, the site commissioning tool may receive point cloud data for warehouse infrastructure and combine bay models with location information (e.g., two-dimensional, three-dimensional, etc.) of the point cloud data to generate accurate representations of the warehouse infrastructure including the location of infrastructure elements and characteristics of the warehouse infrastructure, such as bay opening dimensions. Generating an accurate representation of bay models, and site infrastructure in general, provides a parametric definition of as-built infrastructure. In addition, accurate representations can identify differences between warehouse infrastructure, such as slot size, opening type, and infrastructure characteristics in general. Representations generated for warehouse infrastructure can provide parameters for automated systems to operate within the warehouse infrastructure that was not previously possible due to variability of as-built structures and inconsistencies of data records with actual infrastructure characteristics. Systems and processes described herein can detect errors in warehouse infrastructure and account for deviations from existing plans during an initial commissioning process. As such, the amount of time and on-site visits may be reduced to implement an automated system for a warehouse location. Moreover, detection of errors of an already constructed site is one benefit of systems and methods described herein for site commissioning that generate accurate representations and models of warehouse infrastructure.

According to embodiments, methods are described for site commissioning. By way of example, a method is provided to receive point cloud data for warehouse infrastructure and determine at least one warehouse infrastructure model for the point cloud data. The method can include combining bay models with three-dimensional location data of the point cloud data to generate accurate representations of the warehouse infrastructure, such as an infrastructure model, including the location of infrastructure elements and characteristics of the warehouse infrastructure.

Another embodiment is directed to conditioning point cloud data for use in a site commissioning tool. A method is provided to slice and/or process point cloud data to generate data relevant to a site commissioning tool for commissioning warehouse infrastructure. For example, point cloud data may be processed to generate a presentation of a portion of warehouse, such an aisle rack face. Conditioning point cloud data can include down sampling and/or other processing for at least one of optimizing visual utility, reducing data load, and removal of non-warehouse infrastructure.

Another embodiment is directed to a site commissioning user interface. A site commissioning tool can present a user interface providing graphical display elements to generate accurate representations of warehouse infrastructure. The graphical user interface can display point cloud data for at least a portion of a warehouse, such as an aisle rack face, and provide at least one graphical element for assigning warehouse infrastructure models, such as bay models, to the point cloud data.

Although systems, devices and methods are described herein as relating to warehouses and warehouse infrastructure, it should be appreciated that the principles of the disclosure apply to site commissioning and processing of point cloud data in general.

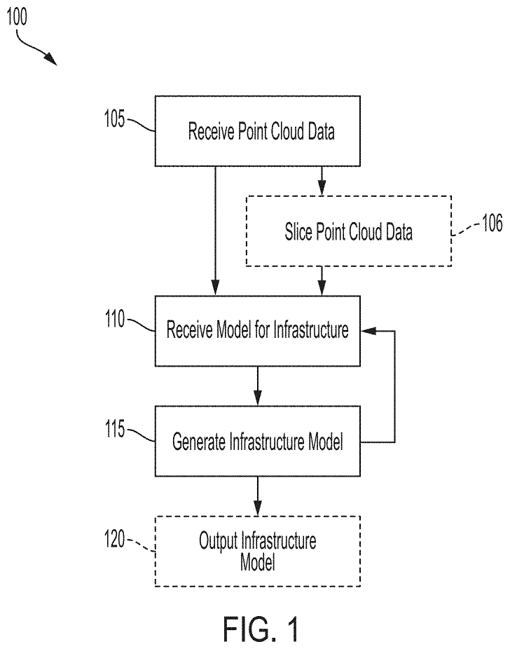

Referring now to FIG. 1, an example process 100 is shown for site commissioning. Site commissioning may include identification of infrastructure and generating data characteristics for infrastructure. Site commissioning for process 100 is described below with reference to a site, such as a warehouse, building site, or infrastructure location in general. It should be appreciated that process 100 may be applied to other locations and is not limited to warehouses or warehouse infrastructure. Due to the size of a warehouse, the varying types of warehouse infrastructure and differences in building construction in general, it may be very time consuming to commission a site. Moreover, deployment of automated systems for a location such as a warehouse may not be successful if the installation of warehouse infrastructure, such as racks, ceiling components, and infrastructure elements in general, deviate from design plans. Process 100 can generate an infrastructure model to account for variances, such as differences in bay model dimensions and deviations from planned installation by generating an infrastructure model to include location data, such as three-dimensional (3D) coordinates for infrastructure elements. Process 100 may be performed by a site commissioning tool. A site commissioning tool as used herein can include a computer program product having a user interface to commission a site.

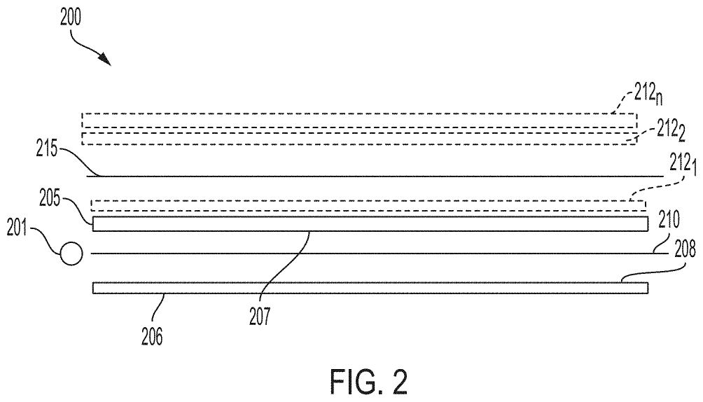

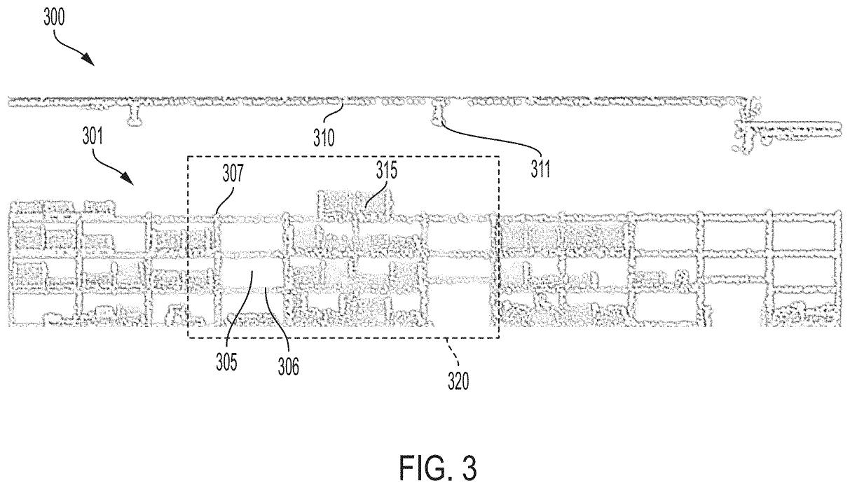

Process 100 includes receiving point cloud data at block 105. Point cloud data, as used herein, includes spatial data representing a site, such as a warehouse, or portion of a site. Point cloud data can include several points (e.g., data points) with each point including coordinates or location data. Coordinates or locations data may be relative to one or more reference points such as a two-dimensional space (2D) or in three-dimensional (3D) space. Point cloud data received at block 105 may be for an entire site (e.g., entire warehouse) and/or for a portion of a site (e.g., an aisle of the warehouse, a rack face, bay, etc.). Point cloud data can be received at block 105 by a site commissioning tool with point cloud data for infrastructure of a site, such as warehouse infrastructure. Point cloud data received at block 105 may be generated by a laser detection and ranging (LiDAR) device using LiDAR measurements to generate data points. Point cloud data may represent a model (e.g., 2D or 3D) for a site, or at least a portion of a site, and include data points for infrastructure (e.g., rack infrastructure) and non-infrastructure elements (e.g., stored items). After slicing, point cloud data may be stored or presented as separate sub-sets of infrastructure elements (‘infrastructure layers’) similar to the concept of layers in CAD software as described below in FIGS. 2 and 3. According to some embodiments, point cloud data is received at block 105 for warehouse infrastructure in order for a site commissioning tool to commission at least one warehouse infrastructure model based on point cloud data. Received point cloud data can include a plurality of data points or points with each point having its own location coordinates. Location coordinates may be relative to one of a two-dimensional and three-dimensional coordinate system. As such, the point cloud data can provide a 2D or 3D representation of objects in space. Embodiments, described herein, such as a site commissioning tool and user interface can display graphical representations of point cloud data a picture or image as 2D or 3D representations. According to embodiments, point cloud data received at block 105 may relate to a 2D plane or space within a distance to a plan, such as a rack face, wall or passageway. Point cloud data may include data in addition to 3D coordinates, such as image data (e.g., pixel data for each point) and/or environmental data for each point characterizing objects associated with each point.

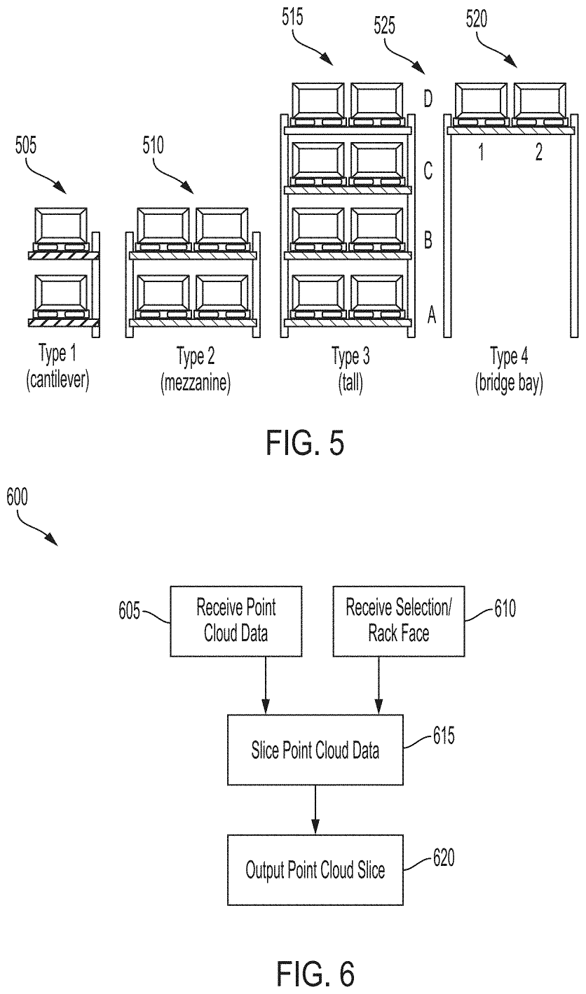

Process 100 may optionally include slicing point cloud data at block 106. Slicing point cloud data as described herein can include selection of point cloud data points, from received point cloud data, for at least a portion of a site. By way of example, slicing of point cloud data can include selection of data points associated with a vertical plane of a warehouse, such as a vertical plane associated with a rack face, and/or all data points within a predetermined distance from a vertical plane. Slicing of point cloud data may include selection of one or more layers of point cloud data associated with a location in a site. Slicing of point cloud data may include reducing data points of point cloud data to reduce the data load on a site commissioning tool. Slicing of point cloud data at block 106 may be optional. As described below in FIG. 6, slicing point cloud data can reduce the data points to process and or provide data points that are relevant to site commissioning. Slicing of point cloud data can generate point cloud data relevant to a portion of a site. According to embodiments, slicing of point cloud data can be used to filter data points for selection of data points associated with infrastructure or physical objects to be modeled.

Process 100 includes receiving a model for infrastructure at block 110. The model received at block 110 may be for at least a portion of point cloud data. According to one embodiment, process 100 is performed to commission a site and includes identification of the infrastructure of a site, and assigning at least one model to the infrastructure using model matching on point cloud data. A site commissioning tool as described herein can associate 3D point cloud coordinates with at least one model such that the model provides a representation of infrastructure, coordinates of the infrastructure, and accurate representation of the dimensions of the infrastructure. Receiving a model for infrastructure can include receiving a selection of a model by a site commissioning tool for a least a portion of warehouse infrastructure. By way of non-limiting example, a model of rack bays may be selected in the site tool for at least a portion of a rack face. At least one model for the warehouse infrastructure may be determined at block 110 of process 100.

Process 100 may use one or more model types for warehouse infrastructure at block 110. Process 100 may use models for graphical overlay onto a representation of point cloud data for warehouse infrastructure, such as of an aisle rack to construct an accurate representation of the aisle rack. In combination with and/or separately with bay models, process 100 can use at least one of obstacle models, fixed and/or mobile automation interaction point models, and models for points of egress/ingress for hazard assessment (e.g., identifying stop zones for devices or location of speed restriction tags at bridge bays).

According to embodiments, a site commissioning tool receives a bay model type selected for a portion of point cloud data. For example, a user interface may display a graphical representation of point cloud data and the model may be received by the device for a portion of the point cloud data. When the point cloud data relates to a rack face, for example, a bay model may be received. The bay model may be selected from a plurality of bay model types and associated within the site commissioning tool. Models for are not limited to bay models and may including one or more of an obstacle model, aisle rack model, bay opening model, automation interaction point model point of egress model and hazard model. According to embodiments, receiving model includes detecting overlay of the model, which may be a graphical element within the site commissioning tool, to the display of the point cloud. Location of the model placement or overlay may be detected and used by the site commissioning tool for one or more of matching models to point cloud data and linking models to generate an infrastructure model.

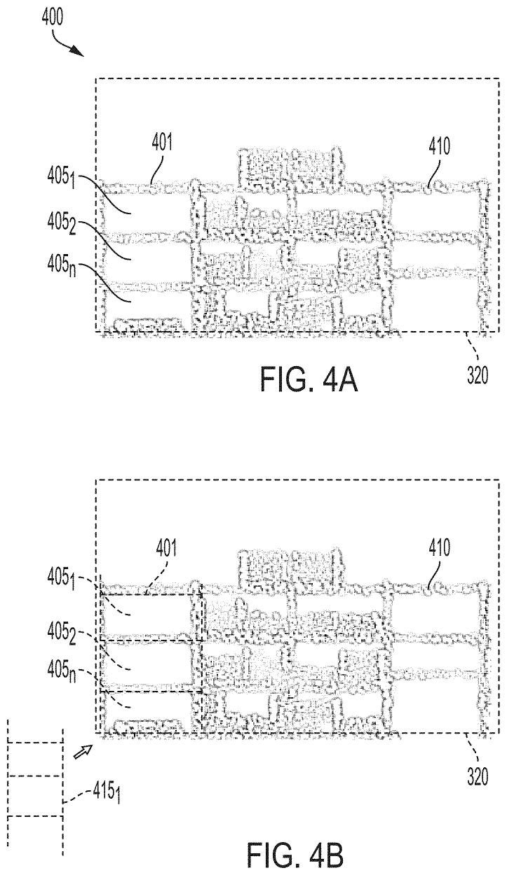

Process 100 can include generating an infrastructure model at block 115 based on at least one received model for infrastructure at block 110. Based on a selected model, the site commissioning tool may incorporate coordinates of the point cloud data for at least one layer of the point cloud data to the infrastructure model. A plurality of infrastructure model selections may be made, and the selections may be combined to generate an infrastructure model for a site at block 115. As described in FIGS. 4A-4D, a site commissioning tool can select models for different sections of warehouse infrastructure, such as different sections of a rack face. Process 100 can include receiving additional models for infrastructure at block 110 and then update an initial infrastructure model at block 115 based on the additional models received. According to some embodiments, generating an infrastructure model at block 115 includes combining received bay models for a rack face of a warehouse with 3D location coordinates of the point cloud data to generate accurate representations of the warehouse infrastructure. The site commissioning tool can match locations of an infrastructure model with location of infrastructure elements and characteristics of the warehouse infrastructure provided by the point cloud data at block 115 based on the overlay of models to point cloud data. As such, the site commissioning tool can generate an infrastructure model based on models determined and/or selected for point cloud data. Process 100 can be performed by a site commissioning tool to generate an accurate representation of an aisle rack in a warehouse using point cloud data for the aisle rack and at least one infrastructure model (e.g., bay model, etc.). Process 100 can be performed to construct an accurate representation of the aisle rack. The infrastructure model generated at block 115 can provide parametric definitions of as-built storage infrastructure in the warehouse. Similarly, the infrastructure model at block 115 can provide a quality assurance document which allows a user to identify differences between slots of warehouse infrastructure commissioned against the physical slots present.

According to embodiments, generating the infrastructure model includes receiving a plurality of models for the point cloud data and combining model selections. The model selections may be one or more types of models. Moreover, the location of the models and placement within a user interface may be detected and used to combine the models. According to embodiments, the infrastructure model is generated by matching locations of the infrastructure model with a location of infrastructure elements using the point cloud location data (e.g., location coordinates).

Process 100 may optionally include outputting an infrastructure model at block 120. Output of an infrastructure model can include output to a display device, such as a user interface. According to other embodiments, output of the infrastructure model can include output to a storage device, such as memory of the commissioning tool. When infrastructure for the site includes warehouse infrastructure, and the infrastructure model includes a model for at least one warehouse rack including a plurality of bays. Output may include display of the warehouse rack for use in provisioning storage, placing objects, planning and/or redesign of the rack face.

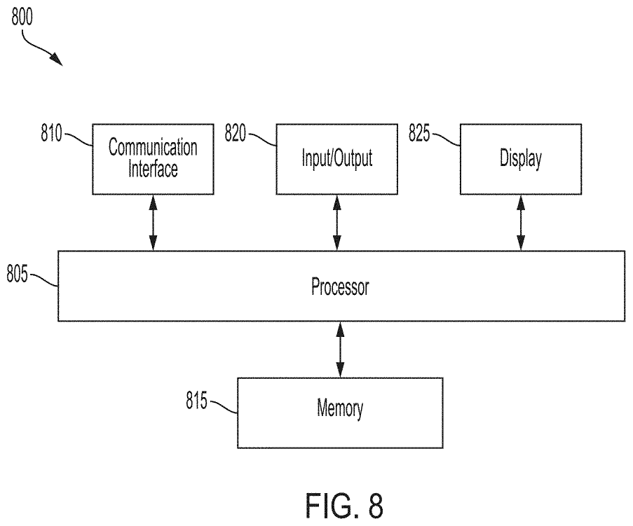

According to embodiments, process 100 may be performed by a site commissioning tool, such as the site commissioning tool of FIG. 8.

FIG. 2 illustrates an example representation of warehouse infrastructure. A plan view is shown in FIG. 2 of an example site including warehouse infrastructure 200. Warehouse infrastructure 200 may include one or more storage racks 205, 206 with aisle 210 between racks 205, 206. Warehouse infrastructure 200 also includes storage racks 212₁₋ₙ and aisle 215. An example entry point 201 is shown for aisle 210. Racks 205 and 206 can include at least one storage configuration of tiers, shelfs, uprights, bays etc. Rack face 207 of rack 205 and rack face 208 of rack 206 each face aisle 210. Rack faces 207, 208 may include bays for storage with bays accessed from aisle 210. Bays as used herein can include storage locations of a rack. Entry point 201 may be associated with a coordinate system wherein the coordinate system of point cloud data may be matched to a coordinate system for location of warehouse infrastructure 200.

Processes and configurations described herein can be applied to sites having many racks and aisles. In addition, processes and configurations described herein can use point cloud data for an entire site and include point cloud data for all of warehouse infrastructure 200, including point cloud data for racks 205 and 206 of aisle 210, and racks 212₁₋ₙ. Point cloud data may be generated by a scanning device operating relative to aisle 210 scanning data for the entire rack faces of racks 205 and 206. Point cloud data for warehouse infrastructure 200 may be categorized by layers, such as layers in physical space/depth, layers associated with a rack face, and/or layers associated with depth/object type. Site commissioning tool configurations provide operations to slice point cloud data for a particular rack face, such as rack face 207 of rack 205. The site commissioning tool also provides models, such as bay models, to be graphically overlaid to point cloud data for a rack face, such as rack face 207.

Warehouse infrastructure 200 includes a plurality of aisles 210 and 215 that can include various bay configurations and may include tiers or levels of shelving that rise several feet (e.g., greater than 30 feet/9 meters) in height. As such, it may be difficult to ascertain dimensions and accurate representations of warehouse infrastructure, such as a bay dimension, due to the height and potential variances of each bay and bay configuration. Processes and configurations discussed herein provide solutions to generate accurate representations.

FIG. 3 illustrates an example representation of point cloud data 300 for warehouse infrastructure. Point cloud data 300 may represent point cloud data for at least a portion of a site including warehouse infrastructure. Point cloud data 300 illustrates a planar representation of warehouse infrastructure, such as rack face 301 (e.g., rack face 207) of a rack (e.g., rack 205). Point cloud data 300 may include one or more layers of data. Rack face 301 includes bays, such as bay 305, shelves, such as shelving 306, and uprights, such as upright 307. Point cloud data 300 may include points for infrastructure associated with a ceiling 310, such as ceiling element 311. Point cloud data 300 may include points for stored items 315 that not part of the warehouse infrastructure.

According to some embodiments, point cloud a portion of point cloud data 301 associated with warehouse structure may be used by a site commissioning tool for site commissioning. Portion 320 may be a portion of rack face 301 that may be received by a site commissioning tool. A site commissioning tool as described herein can receive point cloud data 300 and additional data for an entire site according to some embodiments. Point cloud data 300 may relate to a portion of 3D point cloud data for a site, such as a vertical plane associated with a rack face.

Point cloud data 300 can include points, in a 3D global coordinate system, that define objects. A site commissioning tool as described herein can use point cloud data 300 and the coordinate system of the point cloud data to generate an accurate model and to use the coordinate system for commissioning tools and/or location aware devices and systems, such as autonomous vehicles. Point cloud data 300 can include coordinates of objects in the point cloud, such that a site commissioning tool can generate one or more of outlines and representations of physical objects (e.g., obstacles, lights, skylights) using the same global coordinate system for detection of point cloud data. Point cloud data 300 can include intensity data with every scanned point. Point cloud data 300 can also include RGB data (e.g., color, etc.) with every scan. The collection of points of point cloud data 300 can represent all physical objects in a site. By using point cloud data 300, a site commissioning tool does not need a CAD file to commission a site.

FIGS. 4A, 4B, 4C, and 4D graphically illustrate a process for site commissioning of warehouse infrastructure. FIG. 4A shows process 400 for a portion of point cloud data for a warehouse, such as portion 320. Process 400 can be employed by devices, systems and methods described herein for site commissioning including use by a site commissioning tool. Process 400 illustrates operations of a site commissioning tool for graphically overlaying bay models onto point cloud data representing at least a portion of an aisle rack in order to construct an accurate representation of the aisle rack. Process 400 is imitated by receiving point cloud data, such portion 320. In FIG. 4A, point cloud data includes four (4) tiers as an example, with a first bay configuration 401 having a plurality of bays, such as bays 405₁₋ₙ. Point cloud data in FIG. 4A also includes at least one additional bay configuration, such as second bay configuration 410. It should be appreciated that a rack, or rack face, including the same type of bay models, such as a uniform configuration, may still benefit from the principles of the disclosure. By way of example, process 400 can identify at least one error in bay model templates.

FIG. 4A includes point cloud data for bays 405₁₋ₙ, which appear to have the same dimensions and provide a mezzanine configuration of slots, the slots appearing to have the same dimensions. Processes and site commissioning tool configurations described herein can generate a model providing an accurate representation of the slots including slot dimensions and the locations of slot entry points in 3D coordinates and verify any discrepancies in bays or slot dimensions.

FIG. 4B illustrates overlay of model 415₁ to portion 320 of point cloud data. A site commissioning tool can receive a selection of a bay model, such as model 415₁ within the site commissioning tool to describe infrastructure shown in the point cloud data. Point cloud data 401 includes points that identify bays, such as bays 405₁₋ₙ, and 410, and other warehouse infrastructure. A site commissioning tool can provide options for selection, identification and/or specifying a bay model, or other model, to be applied to point cloud data. The site commissioning tool can also allow for receiving models for a portion of the point cloud data, such as specifying a model 415₁ for aa section of the point cloud data such as bays 405₁₋ₙ. Additional models may be received by way of the site commissioning tool to generate a complete representation of the point cloud data.

FIG. 4C illustrates overlay of model 415₂ to portion 320 of point cloud data which has already be overlaid by model 415₁. A site commissioning tool can receive a selection of a bay model 415₂, to further generate a model for warehouse infrastructure. Models, such as model 415₁ and model 415₂, may be positioned (e.g., dragged and dropped, identification of start and end positions, etc.) to overlay a display of the point cloud data in the site commissioning tool. As such a user can match one or more models to actual representations of warehouse infrastructure. According to some embodiments, when models are overlaid to point cloud data, the site commissioning tool uses point cloud data to represent structural elements of a model. By way of example, lines of model 415 may then represent coordinate data associated with the shapes, such that an upright, shelf, beam or other portion of the models is associated with 3D coordinate data of the point cloud. In certain embodiments, models are overlaid with a site commissioning tool to identify openings of bays or slots, such as bays 405₁₋ₙ such that the openings of infrastructure may be used to define the rack face structure. A site commissioning tool as described herein includes at least one feature to identify mismatch of a bay model with point cloud data. The site commissioning tool may receive one or more inputs to edit the bay model and to achieve a proper match.

FIG. 4D illustrates an example infrastructure model 420 generated for a portion of point cloud data 320 (point cloud data not shown in FIG. 4D). Model 420 includes representations for bays 425₁₋ₙ of different sizes and includes warehouse infrastructure uprights 430 and shelves 435. The site commissioning tool can use 3D coordinate data of point cloud data and models overlaid to the point cloud data to generate model 420 having coordinate data to define locations of infrastructure and coordinates/dimensions of openings. The site commissioning tool can determine bay dimensions, such as dimension 440. Dimensions by the site commissioning tool can include bay width, bay height, width between uprights, beam height, and slot depth. Dimensions can be determined based on coordinate of the point cloud data.

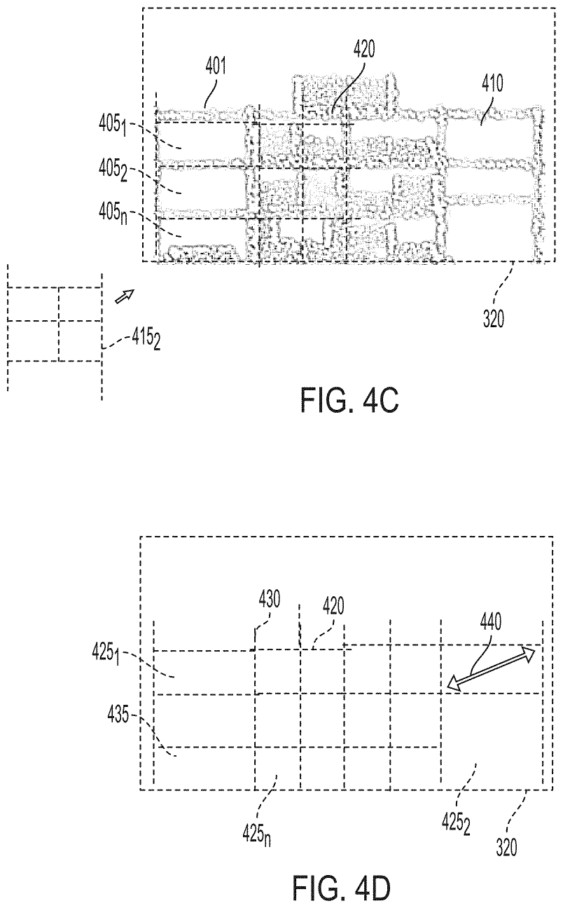

FIG. 5 graphically illustrates examples of bay models. A site commissioning tool can utilize a plurality of models, or templates, to characterize point cloud data and generate a representation of warehouse infrastructure. As used herein, a bay model can include at least one element to describe structural elements of warehouse features, such as a warehouse rack face or warehouse storage bay. Exemplary models for bays of a warehouse rack include a cantilever model 505, mezzanine model 510, tall model 515, and bridge bay model 520. Cantilever model 505 includes a single upright and at least one shelf. Mezzanine model 510 and tall model 515 each include shelves between uprights, with the tall model including more than two shelves. Bridge bay model 520 can include an elevated shelf between two uprights. FIG. 5 also illustrates alphanumeric codes 525 which may be used by the site commissioning tool to label bays of a model. Bays in a warehouse may include unique location labels to establish the association between the physical locations in the warehouse and the logical representation, as stored in an electronic storage system such as a warehouse management system. The site commissioning tool can label bays with location labels and provide spatial data of slots with data for each bay.

It should be appreciated that the processes and site commissioning tool described herein can use other models including at least one of localization reference points (which may include beacons, reflectors, tags or other reference points) tag layout models, obstacle models and models of fixed or mobile automation interaction points, points of egress/ingress for hazard assessment (e.g. identification of necessary stop or speed restriction zones for hazardous areas).

FIG. 6 illustrates process 600 for conditioning point cloud data for a site commissioning tool. Process 600 includes operations to condition point cloud data for use in a site commissioning tool. Process 600 may be initiated by receiving point cloud data at block 605. Process 600 also includes receiving a selection/rack face at block 610. The site commissioning tool can allow for commissioning a site, such as a warehouse site including racks by generating models for each rack using point cloud data of each rack. Portions of the received point cloud in block 605 may need to be sliced to select/filter the point cloud data for a particular rack face.

At block 615, process 600 includes slicing point cloud data. Slicing point cloud data as used herein can include selection of at least a portion of point cloud data and/or processing point cloud data for a site commissioning tool. By way of example, slicing or otherwise processing point cloud data to generate data relevant to a portion of a site, such as aisle racks only. Alternatively or in combination, down sampling or otherwise processing of point cloud data may be performed to optimize utility (visualization-vs-data load). Slicing of point cloud data at block 615 can include removal of non-warehouse infrastructure. For example, slicing of point cloud data at block 615 can include extracting data describing the storage infrastructure locations in 3D and discarding everything irrelevant to commissioning. The extracted slices of the point cloud are used to visualize the slot locations as-built as a reference for accurate parametric commissioning of the slot locations.

Slicing of point cloud data at block 615 can include identification of features in point cloud data for use in commissioning an automated system. By way of example, point cloud data may be sliced to identify one or more of a value-added location-based feature of manual forklifts and commissioning storage infrastructure, obstacles, and navigation features. Slicing of point cloud data at block 615 can include uniform down sampling for at least one of obstacle height editing. Points of objects in a point cloud data may be sorted by a depth coordinate (i.e. if x-coordinate represents the width of the rack face, and z-coordinate represents height, y-coordinate will be orthogonal to the screen and will be representing depth). In some embodiments, a color gradient function is calculated for each depth within the point cloud, and the points are drawn starting from the back using the color, representing the depth on the color gradient. The size of each point is a linear function of depth, such that the closer the point is to the front, the larger it appears on screen. As a result, the points at the back may be drowned out by the larger points on the front of the point cloud, creating an appearance of the front surface of the object. In some scenarios, especially in case of commissioning a rack face with product, the depth-color-coding makes it easier to distinguish the horizontal beams from the product.

Process 600 includes outputting at least one point cloud slice at block 620. A point cloud slice may relate to point cloud data for a rack face.

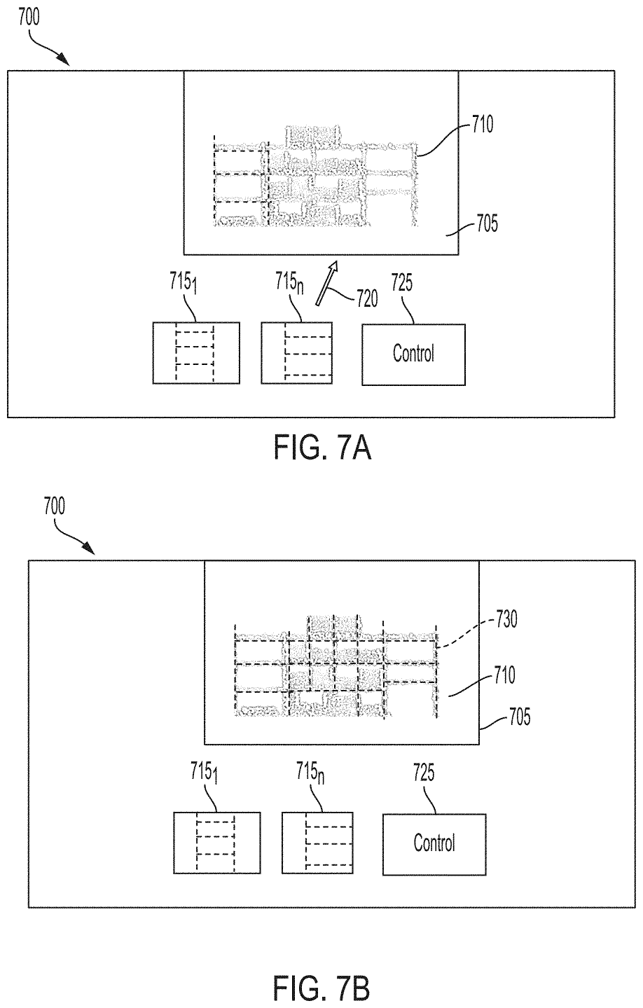

FIGS. 7A and 7B graphically illustrate a site commissioning user interface. A site commissioning tool as described herein can be executed by a computing device to present a graphical user interface. The graphical user interface of the site commissioning tool presents graphical display elements to generate accurate representations of warehouse infrastructure. User interface 700 may be a graphical user interface for display of point cloud data for at least a portion of a warehouse, such as an aisle rack face, and provide at least one graphical element for assigning warehouse infrastructure models, such as bay models, to the point cloud data or vice versa for placement and quality assurance purposes.

FIG. 7A illustrates an example user interface 700 including display window 705 to present point cloud data 710. User interface 700 may be a site commissioning user interface. User interface 700 also can present graphical elements to select models, such as graphical representations of models 715₁₋ₙ and one or more controls, such as control element 725. User interface 700 is configured for overlay of models, such as model 715ₙ to point cloud data 710 in display window 705. Control element 725 represents a control element that can allow for one or more of adjusting models to point cloud data and user interface operations in general of a site commissioning tool.

FIG. 7B illustrates the addition of model 730 to point cloud data 710 to generate a model of warehouse infrastructure associated with the point cloud data. In association of selecting models for bays, each bay can be numbered. In addition, the user interface can allow for infrastructure models to be appended for use with automation systems. By way of example, user interface 700 can be configured to provide accurate commissioning of locations for pallet positions (i.e., slots) in as-built warehouse infrastructure. Visual references of slot locations in the coordinate frame of the site commissioning tool reduce requirements to tune systems after deployment. User interface 700 and a site commissioning tool as described herein may operate for at least one of modeling warehouses, and forklift operations. Models of the site commissioning tool can include parameters for at least one of commissioning, deployment of devices, chambers, sections, aisles, rack faces, uprights, pallet positions, parametric commissioning, location labels, slot labels, slot identifiers, automation, racks, racking, auto-positioning, mapping, slot commissioning, and material handling equipment.

FIG. 8 illustrates a site commissioning tool configuration. According to embodiments, a site commissioning tool may be a device or system or devices configured to generate infrastructure models for infrastructure of a site. Site commissioning tool 800 may include one or more components. Site commissioning tool 800 may be part of a system and/or incorporated into a device. According to embodiments, site commissioning tool 800 includes processor 805, communication interface 810, memory 815, input/output interface 820 and display 825.

Processor 805 may relate to a processor or control device configured to execute one or more operations stored in memory 815, such as processes for site commissioning. Memory 815 may be a non-transitory computer-readable memory storing instructions processor 805. Processor 805 may be coupled to memory 815, I/O 820 and communication interface 810. Processor 805 may be configured to control operations based on one or more inputs from I/O block 820.

Processor 805 may be configured to perform one or more processes herein including process 100 of FIG. 1, and process 600 of FIG. 6. Site commissioning tool 800 may be configured to receive data using at least one receiver of communication interface 810 including point cloud data for infrastructure of a site. Site commissioning tool 800 may receive point cloud data generated by a laser detection and ranging (LiDAR) device using LiDAR measurements to generate data points.

According to embodiments, processor 805 may include one or more processors to execute the instructions of memory 815 to perform a plurality of functional operations using the point cloud data and at least one model, the plurality of functional operations including receiving at least one model for at least a portion of the point cloud data, and generating an infrastructure model for the infrastructure of the site, wherein coordinates of the point cloud data are incorporated with the at least one model. Models may be received by one or more of communication interface 810 and/or input putout interface 820. When site commissioning tool 800 presents a user interface, controls for site commissioning tool 800 may allow for selections of models using the input/output interface 820. Processor 805 may store, using memory 815, the infrastructure models for the infrastructure. Processor 805 may direct display of infrastructure models on display 825.

It should now be understood that embodiments of the present disclosure are directed to systems and methods for commissioning a site with a site commissioning tool. Embodiments use point cloud data and at least one model for infrastructure. An infrastructure model is generated based on the point cloud data and received model such that coordinate data of the point cloud and received models provide an accurate model of warehouse infrastructure.

Having described the subject matter of the present disclosure in detail and by reference to specific embodiments thereof, it is noted that the various details disclosed herein should not be taken to imply that these details relate to elements that are essential components of the various embodiments described herein, even in cases where a particular element is illustrated in each of the drawings that accompany the present description. Further, it will be apparent that modifications and variations are possible without departing from the scope of the present disclosure, including, but not limited to, embodiments defined in the appended claims. More specifically, although some aspects of the present disclosure are identified herein as preferred or particularly advantageous, it is contemplated that the present disclosure is not necessarily limited to these aspects.

1. A system for site commissioning, the system comprising:
at least one receiver configured to receive point cloud data for infrastructure of a site; and
at least one site commissioning processor configured to
perform a plurality of functional operations using the point cloud data and at least one model, the plurality of functional operations including
receive at least one model for at least a portion of the point cloud data; and
generate an infrastructure model for the infrastructure of the site, wherein coordinates of the point cloud data are incorporated with the at least one model.

2. The system of claim 1, wherein point cloud data includes a plurality of points and includes location coordinates for each point in a coordinate system, and wherein the coordinate system is one of a two-dimensional and three-dimensional coordinate system.

3. The system of claim 1, wherein the at least one model is a bay model type selected for the portion of the point cloud data, and wherein the site commission tool is configured to operate with a plurality of bay model types.

4. The system of claim 1, wherein at least one model is at least one of an obstacle model, aisle rack model, bay opening model, automation interaction point model point of egress model and hazard model.

5. The system of claim 1, wherein receiving the at least model includes detecting overlay, by the site commissioning tool, of the at least one model to a display of the point cloud.

6. The system of claim 1, wherein the infrastructure for the site includes warehouse infrastructure, and the infrastructure model includes a model for at least one warehouse rack including a plurality of bays.

7. The system of claim 1, wherein generating the infrastructure model includes receiving a plurality of models for the point cloud data and combining model selections.

8. The system of claim 1, wherein the point cloud data provides location coordinates for infrastructure elements of the site, and wherein generating the infrastructure model includes matching locations of the infrastructure model with location of infrastructure elements.

9. The system of claim 1, wherein the at least one site commissioning processor slices the point cloud data to generate point cloud data relevant to a portion of a site.

10. The system of claim 1, wherein the at least one site commissioning processor outputs the infrastructure model at least one of a display and a storage device.

11. A method for site commissioning with point cloud data, the method comprising:
receiving, by a site commissioning tool, point cloud data for infrastructure of a site;
performing, by the site commissioning tool, a plurality of functional operations using the point cloud data and at least one model, the plurality of functional operations including
receiving at least one model for at least a portion of the point cloud data; and
generating an infrastructure model for the infrastructure of the site, wherein coordinates of the point cloud data are incorporated with the at least one model.

12. The method of claim 11, wherein point cloud data includes a plurality of points and includes location coordinates for each point in a coordinate system, and wherein the coordinate system is one of a two-dimensional and three-dimensional coordinate system.

13. The method of claim 11, wherein the at least one model is a bay model type selected for the portion of the point cloud data, and wherein the site commission tool is configured to operate with a plurality of bay model types.

14. The method of claim 11, wherein at least one model is at least one of an obstacle model, aisle rack model, bay opening model, automation interaction point model point of egress model and hazard model.

15. The method of claim 11, wherein receiving the at least model includes detecting overlay, by the site commissioning tool, of the at least one model to a display of the point cloud.

16. The method of claim 11, wherein the infrastructure for the site includes warehouse infrastructure, and the infrastructure model includes a model for at least one warehouse rack including a plurality of bays.

17. The method of claim 11, wherein generating the infrastructure model includes receiving a plurality of models for the point cloud data and combining model selections.

18. The method of claim 11, wherein the point cloud data provides location coordinates for infrastructure elements of the site, and wherein generating the infrastructure model includes matching locations of the infrastructure model with location of infrastructure elements.

19. The method of claim 11, further comprising slicing the point cloud data to generate point cloud data relevant to a portion of a site.

20. The method of claim 11, further comprising outputting the infrastructure model at least one of a display and a storage device.
